(19) United States
(12) Patent Application Publication
(10) Pub. No.: US 2026/0125787 A1
(43) Pub. Date: May 7, 2026

(54) MASK FOR DEPOSITION, METHOD OF MANUFACTURING THE MASK FOR DEPOSITION, METHOD OF MANUFACTURING DISPLAY DEVICE

(71) Applicant: Samsung Display Co., LTD., Yongin-si (KR)

(72) Inventor: Sung Woon KIM, Yongin-si (KR)

(21) Appl. No.: 19/268,290

(22) Filed: Jul. 14, 2025

(30) Foreign Application Priority Data
Nov. 1, 2024 (KR) 10-2024-0153661

(51) Int. Cl. C23C 14/04; H10K 59/12; H10K 71/16

(52) U.S. Cl. CPC C23C 14/042; H10K 59/1201; H10K 71/166

(57) ABSTRACT

A mask for deposition includes: a base substrate, a first silicon layer covering at least a portion of the base substrate, a second silicon layer located on the base substrate and the first silicon layer, and a plurality of cell opening areas spaced apart from each other. A plurality of first opening patterns overlapping each of the plurality of cell opening areas and passing through the second silicon layer in a third direction are defined in the second silicon layer, at least one second opening pattern passing through the base substrate and the first silicon layer and overlapping the plurality of cell opening areas in the third direction is defined in the base substrate and the first silicon layer, and the second silicon layer includes a first portion spaced apart from the base substrate in the third direction and a second portion contacting a portion of the base substrate.

This application claims priority to Korean Patent Application No. 10-2024-0153661 filed on Nov. 1, 2024, and all the benefits accruing therefrom under 35 U.S.C. § 119, the content of which in its entirety is herein incorporated by reference.

### BACKGROUND

### 1. Field

The disclosure relates to a mask for deposition, a method of manufacturing the mask for deposition, and a method of manufacturing a display device.

### 2. Description of the Related Art

An organic light emitting display device may be used in a mobile device such as a smartphone, a computer, and a tablet personal computer, or an electronic device such as a television, an outdoor billboard, and a display for exhibition.

The organic light emitting display device may include an anode electrode located on a substrate, a cathode electrode, and an organic light emitting layer interposed between the anode electrode and the cathode electrode. The organic light emitting layer may be formed using a mask for deposition.

### SUMMARY

An object of the disclosure is to provide a mask for deposition for improving reliability of a deposition process while continuously performing the deposition process, a deposition apparatus including the same, and a method of manufacturing the mask for deposition.

An object of the disclosure is to provide a mask for deposition manufactured to perform a deposition process with improved reliability, a deposition apparatus including the same, and a display device and an electronic device manufactured according to a method of manufacturing the mask for deposition to improve reliability of driving.

According to embodiments of the disclosure, a mask for deposition includes a base substrate, a first silicon layer covering at least a portion of the base substrate, a second silicon layer located on the base substrate and the first silicon layer, and a plurality of cell opening areas spaced apart from each other. A plurality of first opening patterns overlapping each of the plurality of cell opening areas and passing through the second silicon layer in a third direction are defined in the second silicon layer, at least one second opening pattern passing through the base substrate and the first silicon layer and overlapping the plurality of cell opening areas in the third direction is defined in the base substrate and the first silicon layer, and the second silicon layer includes a first portion spaced apart from the base substrate in the third direction and a second portion contacting a portion of the base substrate.

A thermal expansion rate of the second silicon layer may be greater than a thermal expansion rate of the base substrate.

The first portion may include a (1_a)-th portion and a (1_b)-th portion symmetrically located with respect to a vertical axis parallel to the third direction, and the second portion may include a (2_a)-th portion extending from the (1_a)-th portion and a (2_b)-th portion extending from the (1_b)-th portion.

The base substrate may include an a-th portion overlapping the (1_a)-th portion and a b-th portion overlapping the (2_a)-th portion, and a thermal expansion direction of the b-th portion may be a direction opposite to a thermal expansion direction of the (1_a)-th portion.

A thermal expansion degree of the b-th portion may be less than a thermal expansion degree of the (1_a)-th portion.

The mask for deposition may include a trench overlapping the plurality of cell opening areas in the third direction and recessed in a first direction or a direction opposite to the first direction crossing the third direction.

The trench may include a first trench recessed in the direction opposite to the first direction and overlapping the (1_a)-th portion, and a second trench recessed in the first direction and overlapping the (1_b)-th portion.

The trench may overlap the first portion in the third direction, and may not overlap the first opening patterns in the third direction.

The first silicon layer may include silicon oxide, and the second silicon layer may include silicon nitride.

According to embodiments of the disclosure, a method of manufacturing a mask for deposition includes: forming a first silicon layer on a base substrate; patterning the first silicon layer to form first to third units corresponding to first to third cell opening areas, respectively; forming a second silicon layer on the base substrate and the first silicon layer; patterning the second silicon layer to form first preliminary opening patterns in each of the first to third cell opening areas; removing at least a portion of each of the second silicon layer and the base layer so that a back surface of the first silicon layer is exposed; and removing the first to third units.

Removing the first to third units may be performed in a wet etching process.

A thermal expansion rate of the second silicon layer may be greater than a thermal expansion rate of the base substrate.

The second silicon layer may include a first portion spaced apart from the base substrate in a third direction and a second portion contacting a portion of the base substrate, the first portion may include a (1_a)-th portion and a (1_b)-th portion symmetrically located with respect a vertical axis parallel to the third direction, and the second portion may include a (2_a)-th portion extending from the (1_a)-th portion and a (2_b)-th portion extending from the (1_b)-th portion.

The base substrate may include an a-th portion overlapping the (1_a)-th portion and a b-th portion overlapping the (2_a)-th portion, and a thermal expansion direction of the b-th portion may be a direction opposite to a thermal expansion direction of the (1_a)-th portion.

A thermal expansion degree of the b-th portion may be less than a thermal expansion degree of the (1_a)-th portion.

A trench overlapping one of the first to third cell opening areas in the third direction and recessed in a first direction or a direction opposite to the first direction crossing the third direction may be included.

In removing the first to third units, one of the first to third units may be removed and the trench may be formed in a location of the one of the first to third units.

According to an embodiment of the disclosure, a method of manufacturing a display device includes forming a pixel circuit layer on a substrate, and forming a light emitting element on the pixel circuit layer. Forming the light emitting element includes depositing a light emitting layer using a deposition apparatus, the deposition apparatus includes a mask for deposition including a base substrate, a first silicon layer covering at least a portion of the base substrate, a second silicon layer located on the base substrate and the first silicon layer, and a plurality of cell opening areas spaced apart from each other, a plurality of first opening patterns overlapping each of the plurality of cell opening areas and passing through the second silicon layer in a third direction are defined in the second silicon layer, at least one second opening pattern passing through the base substrate and the first silicon layer and overlapping the plurality of cell opening areas in the third direction is defined in the base substrate and the first silicon layer, and the second silicon layer includes a first portion spaced apart from the base substrate in the third direction and a second portion contacting a portion of the base substrate.

According to embodiments of the disclosure, a mask for deposition for improving reliability of a deposition process while continuously performing the deposition process, a deposition apparatus including the same, and a method of manufacturing the mask for deposition may be provided.

According to embodiments of the disclosure, a mask for deposition manufactured to perform a deposition process with improved reliability, a deposition apparatus including the same, and a display device and an electronic device manufactured according to a method of manufacturing the mask for deposition to improve reliability of driving may be provided.

### BRIEF DESCRIPTION OF THE DRAWINGS

The above and other features of the disclosure will become more apparent by describing in further detail embodiments thereof with reference to the accompanying drawings, in which:

FIG. 1 is a plan view illustrating a mask for deposition according to embodiments of the disclosure;

FIG. 2 is a drawing illustrating an embodiment of a deposition apparatus including the mask for deposition of FIG. 1;

FIG. 3 is a side view illustrating a first area of FIG. 2;

FIG. 4 is a drawing schematically illustrating a changing appearance due to thermal expansion of mask for deposition according to an embodiment;

FIG. 5 is a drawing illustrating a pixel according to embodiments of the disclosure;

FIG. 6 is a cross-sectional view illustrating a display panel including the pixel of FIG. 5;

FIGS. 7 to 13 are drawings illustrating a manufacturing method of manufacturing the mask for deposition of FIG. 1;

FIG. 14 is a drawing illustrating a mask for deposition manufactured according to an embodiment of the disclosure;

FIG. 15 is a plan view illustrating a display device according to an embodiment;

FIG. 16 is a plan view illustrating a sub-pixel according to an embodiment;

FIG. 17 is a cross-sectional view taken along line I-I′ of FIG. 16;

FIG. 18 is a flowchart illustrating a method of manufacturing a display device according to an embodiment;

FIG. 19 is a block diagram illustrating an embodiment of an electronic device including the display device of FIG. 17;

FIG. 20 is a perspective view illustrating an example of a smartphone that may be implemented using the electronic device of FIG. 19; and

FIG. 21 is a perspective view illustrating an example of a tablet computer that may be implemented using the electronic device of FIG. 19.

### DETAILED DESCRIPTION

Hereinafter, a preferred embodiment according to the disclosure is described in detail with reference to the accompanying drawings. It is noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiment described herein. However, the embodiment described herein is provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as “first”, “second”, “a-th”, “(1_b)-th”, “(2_a)-th”, etc. may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, and thus a relationship between one element or feature and another element(s) or feature(s) as shown in the drawings is described. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein may not be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

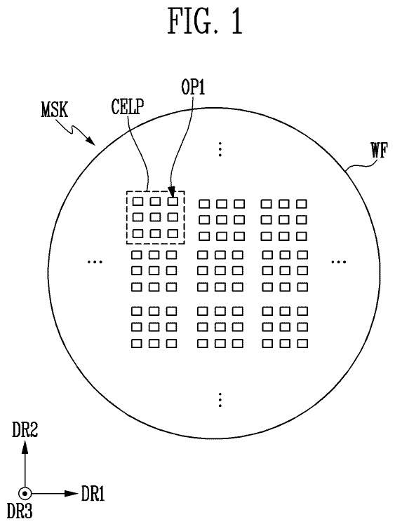

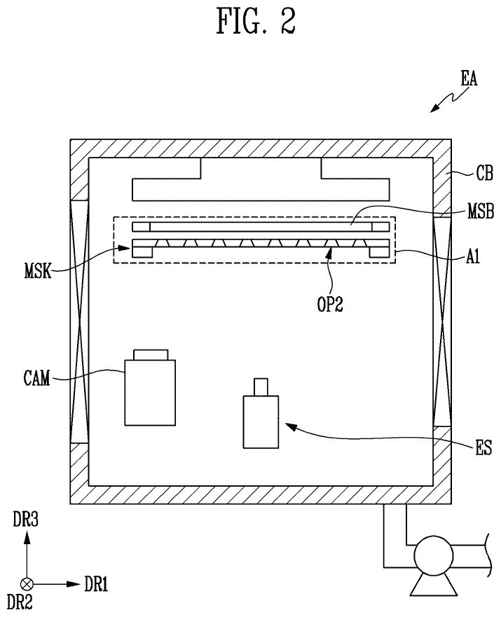

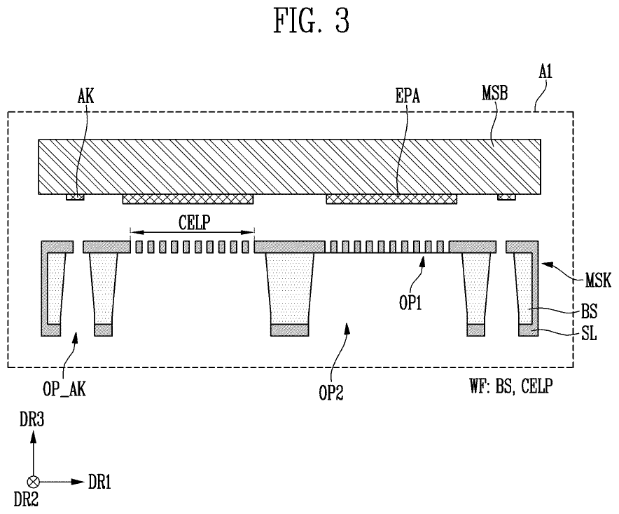

FIG. 1 is a plan view illustrating a mask for deposition according to embodiments of the disclosure. FIG. 2 is a drawing illustrating an embodiment of a deposition apparatus including the mask for deposition of FIG. 1. FIG. 3 is a side view illustrating a first area of FIG. 2. As used herein, the “plan view” is a view in a thickness direction (a third direction DR3) of a mask for deposition MSK or a display device DD.

Referring to FIG. 1, the mask for deposition MSK may include a wafer substrate WF.

The wafer substrate WF may include at least silicon. The wafer substrate WF may have a circular shape in a plan view. However, a material configuring the wafer substrate WF and a planar shape of the wafer substrate WF are not limited thereto. The wafer substrate WF may include various materials and may have various planar shapes.

The wafer substrate WF may include a cell opening area CELP. The mask for deposition MSK may be aligned to face a deposition object (for example, MSB of FIG. 2). The mask for deposition MSK may block a deposition material in a partial area and may not block the deposition material in another partial area. Accordingly, the deposition material may be selectively deposited only in a specific area of the deposition object. The cell opening area CELP may be an area in which the other partial area where the deposition material is not blocked is provided.

For example, in the cell opening area CELP, a plurality of first opening patterns OP1 and a second opening pattern OP2 (refer to FIG. 2) overlapping the first opening patterns in the third direction DR3 may be provided. In this case, the deposition material may be provided to the deposition object through the second opening pattern OP2 and the plurality of first opening patterns OP1.

Using one mask for deposition MSK, deposition may be performed simultaneously on a plurality of deposition objects. In this case, a plurality of cell opening areas CELP may be provided. For example, the plurality of cell opening areas CELP may be arranged along a first direction DR1 and a second direction DR2 crossing the first direction DR1, and may be spaced apart from each other. One second opening pattern OP2 and the plurality of first opening patterns OP1 overlapping the second opening pattern OP2 in the third direction DR3 may be provided in each of the plurality of cell opening areas CELP in case that the plurality of cell opening areas CELP are provided.

Referring to FIGS. 1 and 2, a deposition apparatus EA according to an embodiment may include a chamber CB, a deposition source ES, a camera CAM, and the mask for deposition MSK.

The chamber CB may have a space in an inside. The space inside the chamber CB may be a workspace provided for a deposition process. An object which becomes an object of deposition may be received (or located) inside the chamber CB. For example, a mother substrate MSB may be located inside the chamber CB.

The deposition source ES may be located inside the chamber CB. The deposition source ES may receive a deposition material and supply the received deposition material to an internal space of the chamber CB. The deposition material may include a material that forms a pattern layer (for example, a light emitting layer) on the mother substrate MSB. The deposition source ES may vaporize or sublimate the deposition material by applying energy (for example, heat energy, light energy, vibration energy, or the like) to the deposition material. For example, the deposition source ES may include a heater in the deposition source ES, and the deposition material may be melted or sublimated by heating the deposition material inside the deposition source ES by an operation of the heater. The deposition source ES may be replaceable. The deposition source ES may be replaced with a new deposition source in case that the received deposition material is exhausted.

Referring to FIGS. 1 to 3, a first area A1 may include the mother substrate MSB and the mask for deposition MSK. The mask for deposition MSK may include the wafer substrate WF including the base substrate BS and the silicon layer SL. The mask for deposition MSK may be located between the mother substrate MSB and the deposition source ES.

One cell opening area CELP may correspond to a deposition area EPA. For example, in one cell opening area CELP, a plurality of first opening patterns OP1 passing through the mask for deposition MSK in the third direction DR3 may be provided. In addition, in the cell opening area CELP, a second opening pattern OP2 may be defined. That is, in each of the plurality of cell opening areas CELP, one second opening pattern OP2 and two or more first opening patterns OP1 may overlap in the third direction DR3. In this case, one second opening pattern OP2 and the plurality of first opening patterns OP1 may be integrally formed, and thus the deposition material may be provided to the deposition area EPA through the first and second opening patterns OP1 and OP2.

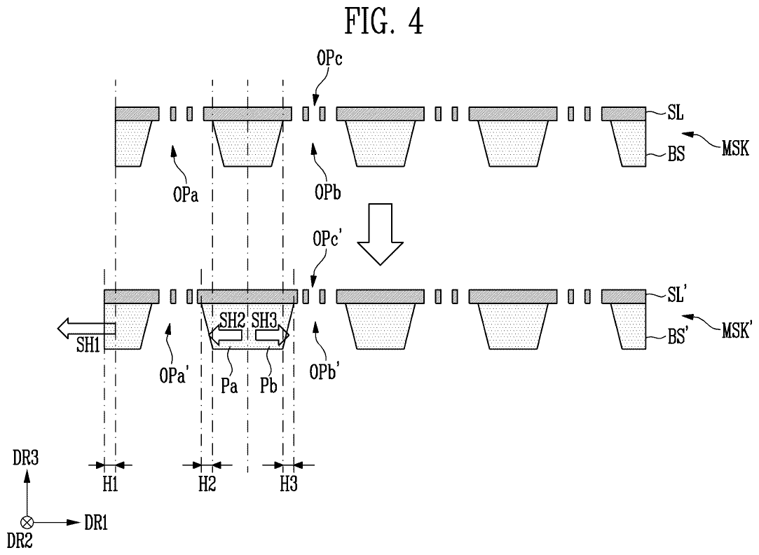

A temperature of the mask for deposition MSK may increase in case that the deposition process continues by the deposition source ES. For example, the temperature of the mask for deposition MSK may increase as the heated deposition material passes through the mask for deposition MSK. In this case, a risk that a width of the first and second opening patterns OP1 and OP2 increases due to thermal expansion of the mask for deposition MSK may occur. Details are described later in FIG. 4.

Referring to FIGS. 1 to 3, the camera CAM may be located inside the chamber CB to aim at a mask assembly 180 and the mother substrate MSB and capture the mask assembly 180 and the mother substrate MSB. For example, the substrate MSB may include an alignment mark AK located on one side. In addition, an alignment mark opening pattern OP_AK may be provided on one side of the mask for deposition MSK. In this case, the camera CAM may capture the alignment mark AK. In other words, the camera CAM may capture whether the alignment mark AK and the alignment mark opening pattern OP_AK are aligned, and based on this, the mask for deposition MSK may be aligned based on the captured image. The camera CAM may be one of various cameras currently known including a charge-coupled device (CCD) camera.

FIG. 4 is a drawing schematically illustrating a changing appearance due to thermal expansion of a mask for deposition according to an embodiment.

Referring to FIGS. 3 and 4, the mask for deposition MSK may include the wafer substrate WF, an a-th opening pattern OPa, a b-th opening pattern OPb, and a c-th opening pattern OPc. Meanwhile, a mask for deposition MSK′ of FIG. 4 may be a mask for deposition that undergoes thermal expansion as the deposition process is progressed. The mask for deposition MSK′ may include a wafer substrate WF′, an a-th opening pattern OPa′, a b-th opening pattern OPb′, and a c-th opening pattern OPc′. In this case, the a-th opening pattern OPa, the b-th opening pattern OPb, the a-th opening pattern OPa′, and the b-th opening pattern OPb′ of FIG. 4 may correspond to one of the second opening patterns OP2 of FIG. 3. In addition, the c-th opening pattern OPc and the c-th opening pattern OPc′ of FIG. 4 may correspond to one of the first opening patterns OP1 of FIG. 3.

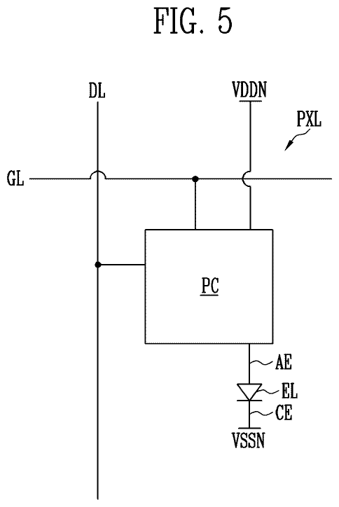

According to an embodiment, first to third shifts SH1 to SH3 may indicates force that induces a length change of the mask for deposition MSK according to the thermal expansion. For example, the mask for deposition MSK may undergo the thermal expansion corresponding to each of the first to third shifts SH1 to SH3, and thus may be changed to the mask for deposition MSK'. That is, as the mask for deposition MSK is heated, the thermal expansion in the first direction DR1 and a direction opposite to the first direction DR1 may occur. In this case, the first shift SH1 may induce a length change of the mask for deposition MSK in the first direction DR1. For example, according to the first shift SH1, one end (one end in the direction opposite to the first direction DR1) of the mask for deposition MSK′ may be expanded and extended by a first length H1 compared to one end of the mask for deposition MSK. Accordingly, a horizontal length (length of the first direction DR1) of the a-th opening pattern OPa′ may be longer than a horizontal length of the a-th opening pattern OPa, and pixels per inch (PPI) of the pixel PXL (refer to FIG. 5) formed by the mask for deposition MSK′ may be increased.

The second shift SH2 may induce a length change of the mask for deposition MSK in the direction opposite to the first direction DR1. For example, according to the second shift SH2, the a-th portion Pa of the base substrate BS′ of the mask for deposition MSK′ may be expanded (or extended) in the direction opposite to the first direction DR1 by a second length H2. In addition, the third shift SH3 may induce a length change of the mask for deposition MSK in the first direction DR1. For example, according to the third shift SH3, the b-th portion Pb of the base substrate BS′ of the mask for deposition MSK′ may be expanded (or extended) in the first direction DR1 by a third length H3. Accordingly, a horizontal length of the b-th opening pattern OPb′ may become different according to a sum of a thermal expansion degree of the second shift SH2 and the third shift SH3. In other words, thermal expansion of the base substrate BS′ may occur in the first direction DR1 in case that a thermal expansion degree according to the third shift SH3 is greater than a thermal expansion degree according to the second shift SH2. Accordingly, a horizontal length (length in the first direction DR1) of the b-th opening pattern OPb′ may become shorter than a horizontal length of the b-th opening pattern OPb, and PPI of the pixel formed by the mask for deposition MSK′ may be decreased.

According to an embodiment, the first to third lengths H1 to H3 may be the same. However, the disclosure is not limited thereto. For example, the second length H2 and the third length H3 may be the same, and the first length H1 may be greater than the second length H2 and the third length H3.

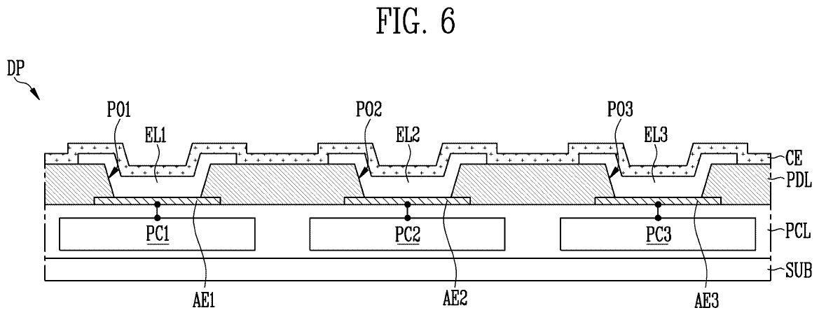

Hereinafter, with reference to FIGS. 5 and 6, a display panel including a pixel manufactured using the mask for deposition MSK is described.

FIG. 5 is a drawing illustrating a pixel according to embodiments of the disclosure.

Referring to FIG. 5, the pixel PXL may include a pixel circuit PC and an organic light emitting layer EL.

The organic light emitting layer EL may be connected between a first power voltage node VDDN and a second power voltage node VSSN. The first power voltage node VDDN may receive a first power voltage. The second power voltage node VSSN may receive a second power voltage. The first power voltage may have a voltage level higher than a voltage level of the second power voltage. In this case, the organic light emitting layer EL may be a configuration corresponding to a light emitting element LD described later or a configuration included in the light emitting element LD.

The organic light emitting layer EL may be connected between an anode electrode AE and a cathode electrode CE. The anode electrode AE may be connected to the first power voltage node VDDN through the pixel circuit PC. For example, the anode electrode AE may be connected to the first power voltage node VDDN through one or more transistors included in the pixel circuit PC. The cathode electrode CE may be connected to the second power voltage node VSSN. The organic light emitting layer EL may be configured to emit light according to a current flowing from the anode electrode AE to the cathode electrode CE.

The pixel circuit PC may be connected to a gate line GL and a data line DL. In response to a gate signal received through the gate line GL, the pixel circuit PC controls the organic light emitting layer EL to emit light according to a data signal received through the data line DL. For these operations, the pixel circuit PC may include circuit elements, for example, transistors and one or more capacitors.

FIG. 6 is a cross-sectional view illustrating a display panel including the pixels of FIG. 5. The display panel DP described in FIG. 6 may substantially correspond to the mother substrate MSB of FIG. 3.

Referring to FIG. 6, the display panel DP may include a substrate SUB, a pixel circuit layer PCL, first to third anode electrodes AE1, AE2, and AE3, first to third organic light emitting layers EL1, EL2, and EL3, a pixel defining layer PDL, and the cathode electrode CE.

The pixel circuit layer PCL may be located on the substrate SUB. The substrate SUB may be substantially the same as the mother substrate MSB of FIG. 2. Hereinafter, an overlapping description is omitted.

The substrate SUB may include an insulating material such as glass or resin. For example, the substrate SUB may include a glass substrate. As another example, the substrate SUB may include a polyimide (PI) substrate. As still another example, the substrate SUB may include a silicon wafer substrate formed using a semiconductor process.

The pixel circuit layer PCL may include insulating layers and semiconductor patterns and conductive patterns located between the insulating layers. The conductive patterns of the pixel circuit layer PCL may function as circuit elements, lines, and the like. The circuit elements of the pixel circuit layer PCL may define first to third pixel circuits PC1, PC2, and PC3. Each of the first to third pixel circuits PC1, PC2, and PC3 may be connected to the gate line GL, the data line DL, and the first power voltage node VDDN of FIG. 5.

The first to third anode electrodes AE1, AE2, and AE3 may be located on the pixel circuit layer PCL. The first anode electrode AE1 may be connected to the first pixel circuit PC1. The second anode electrode AE2 may be connected to the second pixel circuit PC2. The third anode electrode AE3 may be connected to the third pixel circuit PC3.

The pixel defining layer PDL may be located on the pixel circuit layer PCL and the first to third anode electrodes AE1, AE2, and AE3. The pixel defining layer PDL may define first to third pixel openings PO1, PO2, and PO3 that expose portions of the first to third anode electrodes AE1, AE2, and AE3. The pixel defining layer PDL may be configured to include a light blocking material to prevent light mixing between adjacent pixels.

The first organic light emitting layer EL1 may be located on a side surface of the first anode electrode AE1 exposed by the first pixel opening PO1 and the pixel defining layer PDL adjacent to the first anode electrode AE1. The second organic light emitting layer EL2 may be located on a side surface of the second anode electrode AE2 exposed by the second pixel opening PO2 and the pixel defining layer PDL adjacent to the second anode electrode AE2. The third organic light emitting layer EL3 may be located on a side surface of the third anode electrode AE3 exposed by the third pixel opening PO3 and the pixel defining layer PDL adjacent to the third anode electrode AE3. The first to third organic light emitting layers EL1, EL2, and EL3 may include organic materials capable of emitting light based on a signal provided from the first to third anode electrodes AE1, AE2, and AE3.

The cathode electrode CE covering the pixel defining layer PDL and the first to third organic light emitting layers EL1, EL2, and EL3 may be disposed. The cathode electrode CE may be connected to the first to third organic light emitting layers EL1, EL2, and EL3. As described above, the cathode electrode CE may be a common electrode commonly provided with respect to the first to third organic light emitting layers EL1, EL2, and EL3. The cathode electrode CE may be connected to the second power voltage node VSSN of FIG. 5.

A first pixel including the first pixel circuit PC1, the first anode electrode AE1, the cathode electrode CE, and the first organic light emitting layer EL1 interposed between the first anode electrode AE1 and the cathode electrode CE may be provided. Similarly, a second pixel including the second pixel circuit PC2, the second anode electrode AE2, the cathode electrode CE, and the second organic light emitting layer EL2 interposed between the second anode electrode AE2 and the cathode electrode CE may be provided, and a third pixel including the third pixel circuit PC3, the third anode electrode AE3, the cathode electrode CE, and the third organic light emitting layer EL3 interposed between the third anode electrode AE3 and the cathode electrode CE may be provided.

According to an embodiment, the mask for deposition MSK (refer to FIG. 3) may be provided so as to face the display panel DP. In other words, the mask for deposition MSK may be aligned with respect to the display panel DP. In addition, the plurality of first opening patterns OP1 may expose portions of the first to third pixel openings PO1, PO2, and PO3 and the pixel defining layer PDL adjacent to the first to third pixel openings PO1, PO2, and PO3. In this case, the first to third organic light emitting layers EL1, EL2, and EL3 may be deposited on the first to third pixel openings PO1, PO2, and PO3 and the pixel defining layer PDL adjacent to the first to third pixel openings PO1, PO2, and PO3. Thereafter, the mask for deposition MSK may be removed, and the cathode electrode CE described with reference to FIG. 6 may be further formed.

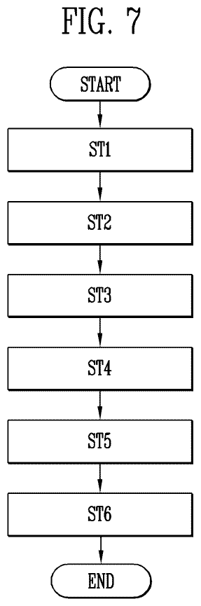

FIGS. 7 to 13 are drawings illustrating a manufacturing method of manufacturing the mask for deposition of FIG. 1. Hereinafter, a description of a content overlapping the content described with reference to FIGS. 1 to 6 is omitted.

Referring to FIG. 7, a method of manufacturing the mask for deposition MSK may include steps 1 to 6 ST1, ST2, ST3, ST4, ST5, and ST6.

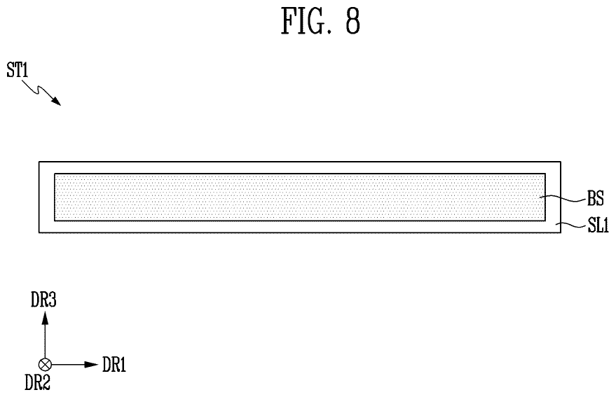

Referring to FIG. 8, a first silicon layer SL1 may be formed on a base substrate BS (step 1: ST1). For example, the first silicon layer SL1 may be applied on the prepared base substrate BS. Here, the base substrate BS may include silicon. In addition, the first silicon layer SL1 may include at least one of a silicon oxide series material.

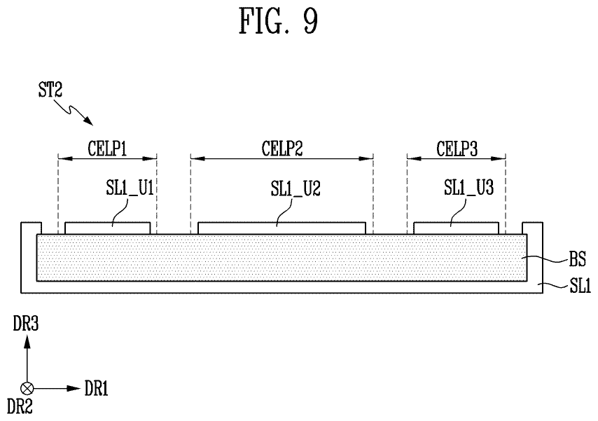

Referring to FIG. 9, the first silicon layer SL1 may be patterned to form first to third units SL1_U1 to SL1_U3 corresponding to the first to third cell opening areas CELP1 to CELP3 (step 2: ST2), respectively. Hereinafter, among the plurality of cell opening areas CELP (refer to FIG. 1), the first to third cell opening areas CELP1, CELP2, and CELP3 are shown. However, the disclosure is not limited thereto. According to an embodiment, a horizontal length of the second unit SL1_U2 may be longer than a horizontal length of the first unit SL1_U1 or the third unit SL1_U3.

In this step, at least a portion of an upper surface of the first silicon layer SL1 may be removed. That is, the upper surface of the first silicon layer SL1 excluding the first to third units SL1_U1 to SL1_U3 may be removed. Accordingly, at least a portion of an upper surface of the base substrate BS may be exposed in the third direction DR3.

In this step, the first silicon layer SL1 may be removed in an etching process. However, this is an example and is not limited thereto.

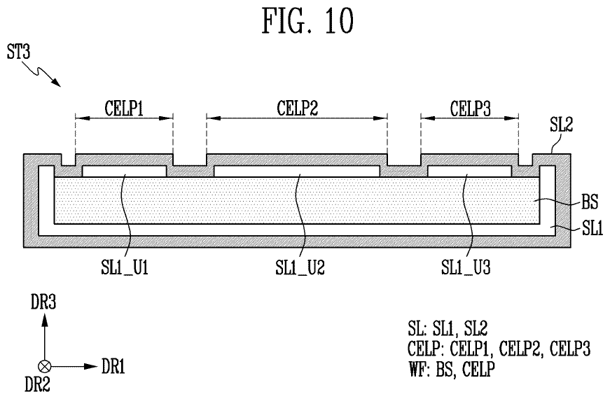

Referring to FIG. 10, a second silicon layer SL2 may be formed on the base substrate BS and the first silicon layer SL1 (step 3: ST3). For example, the second silicon layer SL2 may be located to cover the base substrate BS and the first silicon layer SL1.

The second silicon layer SL2 may include at least one of a silicon nitride series material. However, the disclosure is not limited thereto.

In this step, the second silicon layer SL2 may be formed in a deposition process. According to an embodiment, the second silicon layer SL2 may be formed according to a chemical vapor deposition (CVD) process. However, the disclosure is not limited thereto.

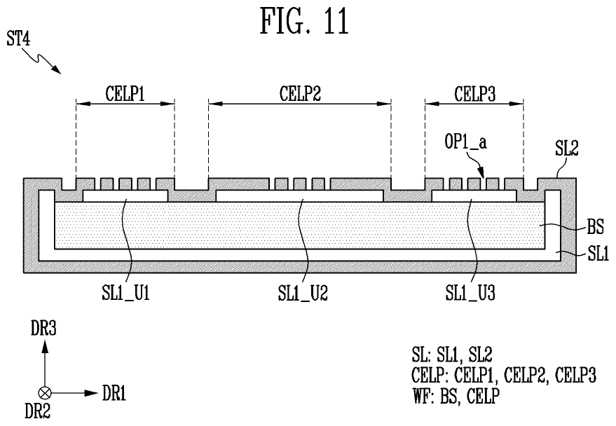

Referring to FIG. 11, the second silicon layer SL2 may be patterned to form first preliminary opening patterns OP1_a in each of the first to third cell opening areas CELP1, CELP2, and CELP3 (step 4: ST4). In this case, a method of patterning the first preliminary opening patterns OP1_a may not be limited, and various methods known in the art may be used. For example, the first preliminary opening patterns OP1_a may be formed using an exposed and developed photoresist material as a mask.

The first preliminary opening patterns OP1_a may overlap each of the cell opening areas CELP. The first preliminary opening patterns OP1_a may correspond to the first opening patterns OP1. That is, the first preliminary opening patterns OP1_a may be a portion of openings through which a deposition material passes in case that the deposition process is performed through the mask for deposition MSK.

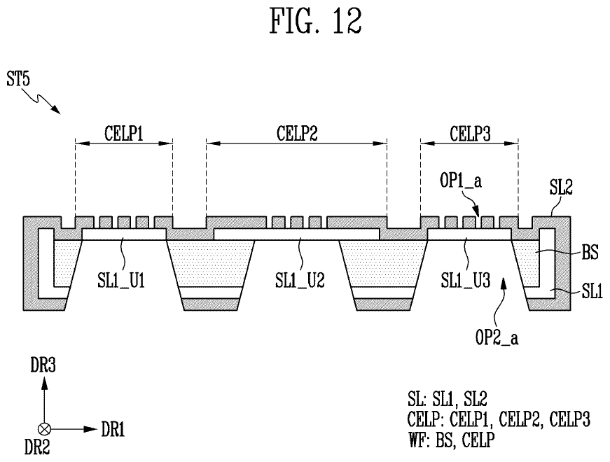

Referring to FIG. 12, at least a portion of each of the second silicon layer SL2 and the base substrate BS may be removed so that a back surface of the first silicon layer SL1 is exposed (step 5: ST5). For example, each of the second silicon layer SL2 and the base substrate BS may be removed through an etching process, and second preliminary opening patterns OP2_a may be formed. In this case, each of the second silicon layer SL2 and the base substrate BS may be removed so that the second preliminary opening patterns OP2_a have a trapezoidal shape. However, a shape of the second preliminary opening patterns OP2_a is not limited thereto.

The second preliminary opening patterns OP2_a may correspond to the second opening patterns OP2. For example, the second preliminary opening patterns OP2_a may be a portion of the openings through which the deposition material passes in case that the deposition process is performed through the mask for deposition MSK.

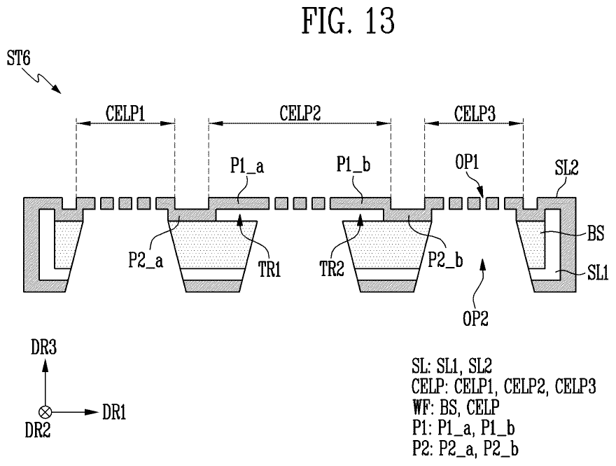

Referring to FIG. 13, the first to third units SL1_U1, SL1_U2, and SL1_U3 may be removed (step 6: ST6). For example, the first to third units SL1_U1, SL1_U2, and SL1_U3 corresponding to the first to third cell opening areas CELP1, CELP2, and CELP3, respectively, may be removed, and the first opening patterns OP1 and the second opening patterns OP2 may be formed. The first and second trenches TR1 and TR2 may be formed in the location from which the second unit SL1_U2 is removed.

The first to third units SL1_U1, SL1_U2, and SL1_U3 may be removed through an etching process. According to an embodiment, the first to third units SL1_U1, SL1_U2, and SL1_U3 may be removed through a wet etching process. Accordingly, the first trench TR1 and the second trench TR2 may be relatively stably formed.

The second unit SL1_U2 may be removed, and the first trench TR1 and the second trench TR2 may be formed. For example, the second silicon layer SL2 may include a first portion P1 and a second portion P2. In this case, for convenience of description, the disclosure is described based on a portion corresponding to the second cell opening area CELP2, but is not limited thereto.

The first portion P1 may not contact the base substrate BS, and the second portion P2 may contact the base substrate BS. For example, the first portion P1 may be spaced apart from the base substrate BS in the third direction DR3 with the first trench TR1 or the second trench TR2 therebetween.

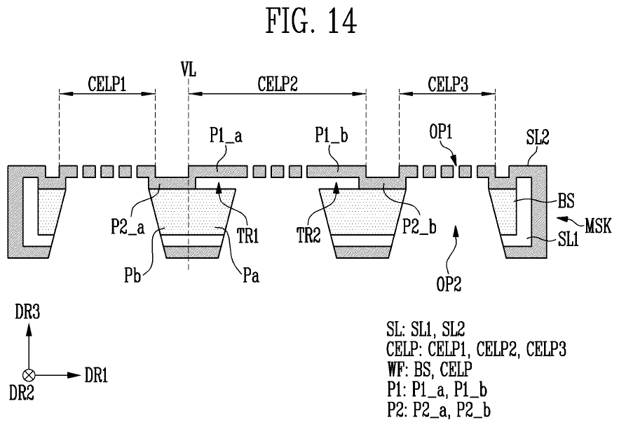

The second portion P2 may extend from the first portion P1 and contact the base substrate BS. As shown in FIG. 14, the second portion P2 may be located in a plane different from a plane where the first portion P1 is located with respect to the third direction DR3. Here, the planes are perpendicular to the third direction DR3.

A (1_a)-th portion P1_a may be a portion of the second silicon layer SL2 overlapping the second cell opening area CELP2 and located in the direction opposite to the first direction DR1 with respect to a center of the second cell opening area CELP2, and a (1_b)-portion P1_b may be a portion of the second silicon layer SL2 overlapping the second cell opening area CELP2 and located in the first direction DR1 with respect to the center of the second cell opening area CELP2.

A (2_a)-th portion P2_a may be a portion of the second silicon layer SL2 located between the first cell opening area CELP1 and the second cell opening area CELP2 and in the direction opposite to the first direction DR1 with respect to the center of the second cell opening area CELP2. The (2_a)-th portion P2_a may extend from the (1_a)-th portion P1_a in the direction opposite to the first direction DR1. A (2_b)-th portion P2_b may be a portion of the second silicon layer SL2 located between the third cell opening area CELP3 and the second cell opening area CELP2 and in the first direction DR1 with respect to the center of the second cell opening area CELP2. The (2_b)-th portion P2_b may extend from the (1_b)-th portion P1_b in the first direction DR1.

The first trench TR1 may be recessed in the direction opposite to the first direction DR1 and may overlap the (1_a)-th portion P1_a in the third direction DR3. The second trench TR2 may be recessed in the first direction DR1 and may overlap the (1_b)-th portion P1_b in the third direction DR3. The first trench TR1 and the second trench TR2 may not overlap the first opening patterns OP1 in the third direction DR3. However, this is an example, and is not limited thereto.

FIG. 14 is a drawing illustrating a mask for deposition manufactured according to an embodiment of the disclosure.

Referring to FIG. 14, the base substrate BS may include an a-th portion Pa and a b-th portion Pb. The a-th portion Pa may be a portion of the base substrate BS in the first direction DR1 with respect to an imaginary vertical line VL. The b-th portion Pb may be a portion of the base substrate BS in the direction opposite to the first direction DR1 with respect to the imaginary vertical line VL.

According to an embodiment of the disclosure, a thermal expansion direction of the (1_a)-th portion P1_a may be the first direction DR1. On the other hand, a thermal expansion direction of the b-th portion Pb may be the direction opposite to the first direction DR1. In this case, a thermal expansion rate of the second silicon layer SL2 may be greater than a thermal expansion rate of the base substrate BS. In other words, a thermal expansion degree of the (1_a)-th portion P1_a may be relatively greater than a thermal expansion degree of the a-th portion Pa (or the b-th portion Pb). Accordingly, a gap between the first opening patterns OP1 overlapping the second cell opening area CELP2 may be relatively reduced (or at least maintained), and the PPI of the pixel PXL (refer to FIG. 5) formed by the mask for deposition MSK may be relatively constant. That is, according to an embodiment of the disclosure, even in case that thermal expansion of the base substrate BS occurs as the deposition process is progressed, a gap between the first opening patterns OP1 may be maintained constant, thereby effectively preventing a risk that reliability of the deposition process is reduced.

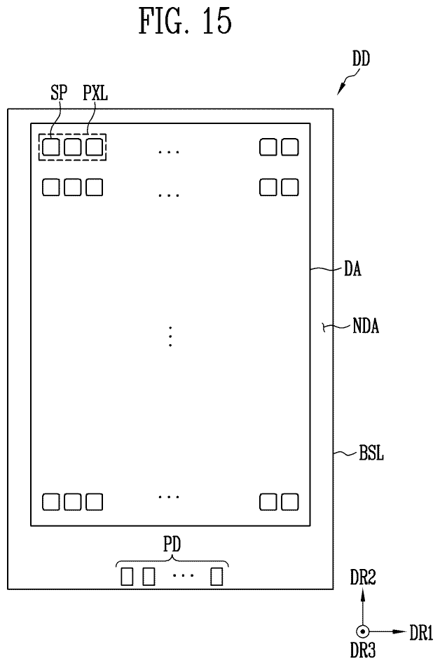

Hereinafter, a display device DD is described with reference to FIGS. 15 to 17.

FIG. 15 is a plan view illustrating a display device according to an embodiment. The display device DD of FIG. 15 may be a display device DD manufactured using the mask for deposition MSK and the deposition apparatus EA described above.

Referring to FIG. 15, the display device DD (or a display panel) may include a display area DA and a non-display area NDA. The display device DD displays an image through the display area DA. The non-display area NDA is located around the display area DA.

The display device DD may include a base layer BSL, sub-pixels SP, and/or pads PD.

The sub-pixels SP are located in the display area DA on the base layer BSL. The sub-pixels SP may be arranged in a matrix form along a first direction DR1 and a second direction DR2 crossing the first direction DR1. However, embodiments are not limited thereto. For example, the sub-pixels SP may be arranged in a zigzag form along the first direction DR1 and the second direction DR2. For example, the sub-pixels SP may be located in a pentile form. The first direction DR1 may be a row direction, and the second direction DR2 may be a column direction. Two or more of the sub-pixels SP may configure one pixel PXL.

A component for controlling the sub-pixels SP may be located in the non-display area NDA on the base layer BSL. For example, lines connected to the sub-pixels SP, such as gate lines and data lines, may be located in the non-display area NDA.

The pads PD are located in the non-display area NDA on the base layer BSL. The display pads PD may be electrically connected to the sub-pixels SP through the lines. For example, the display pads PD may be connected to the sub-pixels SP through the data lines.

Voltages and signals necessary for an operation of components included in the display device DD may be provided from a driver integrated circuit through the pads PD. For example, the data lines may be connected to the driver integrated circuit through the pads PD. For example, power voltages may be received from the driver integrated circuit through the pads PD.

In an embodiment, a circuit board may be electrically connected to the pads PD using a conductive adhesive such as an anisotropic conductive film. In this case, the circuit board may be a flexible circuit board or a flexible film having a flexible material. The driver integrated circuit may be mounted on the circuit board and electrically connected to the pads PD.

In an embodiment, the display area DA may have various shapes. The display area DA may have a closed loop of shape including sides of a straight line and/or a curved line. For example, the display area DA may have shapes such as a polygon, a circle, a semicircle, and an ellipse.

In an embodiment, the display device DD may have a flat display surface. In an embodiment, the display device DD may have at least a partially rounded display surface. The display device DD may be bendable, foldable, or rollable. In such cases, the display device DD and/or the base layer BSL may include materials having a flexible property.

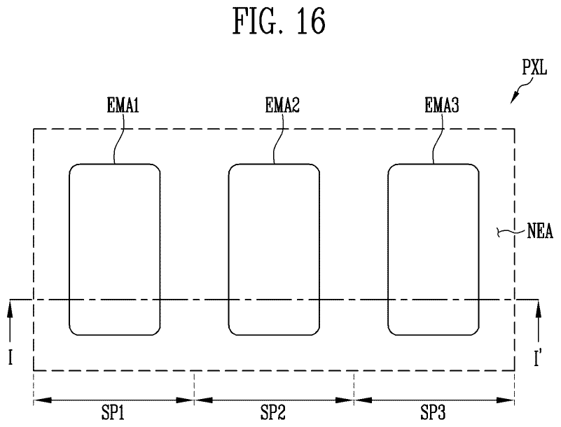

FIG. 16 is a plan view illustrating a sub-pixel according to an embodiment.

Referring to FIG. 16, the pixel PXL may include first to third sub-pixels SP1 to SP3 arranged in the first direction DR1. The pixel PXL of FIG. 16 may be described similarly to the pixel PXL of FIG. 5.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

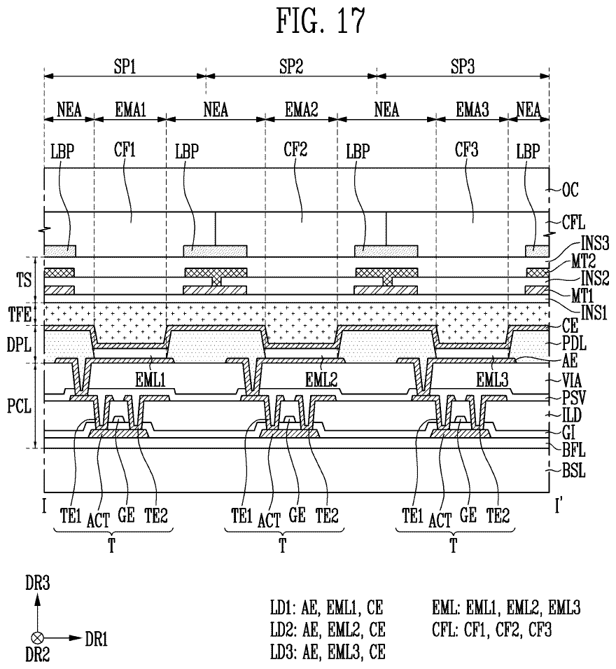

The first emission area EMA1 may be an area where light is emitted from a first light emitting layer EML1 (refer to FIG. 17) of the first sub-pixel SP1. The second emission area EMA2 may be an area where light is emitted from a second light emitting layer EML2 (refer to FIG. 17) of the second sub-pixel SP2. The third emission area EMA3 may be an area where light is emitted from a third light emitting layer EML3 (refer to FIG. 17) of the third sub-pixel SP3.

FIG. 17 is a cross-sectional view taken along line I-I′ of FIG. 16.

Referring to FIG. 17, the first to third sub-pixels SP1 to SP3 may include the emission areas EMA1, EMA2, and EMA3, respectively, and the non-emission area NEA may be positioned between the emission areas EMA1, EMA2, and EMA3 of the first to third sub-pixels SP1 to SP3.

Each of the first to third sub-pixels SP1 to SP3 may include a pixel circuit layer PCL, a display element layer DPL, and/or a thin film encapsulation layer TFE sequentially located on the base layer BSL.

The base layer BSL may form a base surface. The base layer BSL may include a transparent insulating material, and thus may transmit light. The base layer BSL may be a rigid substrate or a flexible substrate. The rigid substrate may be, for example, one of a glass substrate, a quartz substrate, a glass ceramic substrate, or a crystalline glass substrate. The flexible substrate may be one of a film substrate or a plastic substrate including a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate, but is not necessarily limited thereto. For example, the base layer BSL may be a substrate including silicon. According to an embodiment, the display device DD may be an OLED on silicon (OLEDoS) display device including a display panel formed on a silicon substrate. In this case, the base layer BSL of FIG. 17 may include the substrate SUB of FIG. 6. However, the disclosure is not limited thereto.

The pixel circuit layer PCL may include a buffer layer BFL, a gate insulating layer GI, an interlayer insulating layer ILD, a passivation layer PSV, and/or a via layer VIA sequentially stacked on the base layer BSL along the third direction DR3. In this case, the pixel circuit layer PCL of FIG. 17 may be described similarly to the pixel circuit layer PCL of FIG. 6.

The buffer layer BFL may be an inorganic insulating layer including an inorganic material. The buffer layer BFL may include at least one of metal oxides such as silicon nitride (SiNx), silicon oxide (SiOx), silicon oxynitride (SiOxNy), or aluminum oxide (AlOx). The buffer layer BFL may be provided as a single layer, but may also be provided as multiple layers of at least two or more layers. Each layer may include a same material or may include different materials in case that the buffer layer BFL is provided as the multiple layers. The buffer layer BFL may be omitted according to a material, a process condition, and the like of the base layer BSL.

A transistor T may be located on the buffer layer BFL. The transistor T may include an active pattern ACT, a gate electrode GE, a first transistor electrode TE1, and/or a second transistor electrode TE2.

The active pattern ACT may be located on the buffer layer BFL. The active pattern ACT may include a polysilicon semiconductor. For example, the active pattern ACT may be formed through a low-temperature polysilicon process. However, the disclosure is not necessarily limited thereto, and the active pattern ACT may include an oxide semiconductor, a metal oxide semiconductor, or the like.

Each active pattern ACT may each include a channel area, a first contact area connected to one end of the channel area, and a second contact area connected to another end of the channel area. The channel area, the first contact area, and the second contact area may include a semiconductor layer which is not doped with an impurity or is doped with an impurity. For example, the first contact area and the second contact area may include a semiconductor layer doped with an impurity, and the channel area may include a semiconductor layer which is not doped with an impurity. As an impurity, for example, a p-type impurity may be used, but is not limited thereto. One of the first or second contact area may be a source area and the other may be a drain area.

The gate insulating layer GI may be located on the active pattern ACT. The gate insulating layer GI may be an inorganic layer (or an inorganic insulating layer) including an inorganic material. For example, the gate insulating layer GI may include at least one of a metal oxide such as silicon nitride (SiNx), silicon oxide (SiOx), silicon oxynitride (SiOxNy), and aluminum oxide (AlOx). However, a material of the gate insulating layer GI is not limited to the embodiments described above. According to an embodiment, the gate insulating layer GI may include an organic layer (or organic insulating layer) including an organic material. The gate insulating layer GI may be provided as a single layer, but may also be provided as multiple layers of at least two or more layers.

The gate electrode GE may be located on the gate insulating layer GI. The gate electrode GE may overlap the channel area of the active pattern ACT in the third direction DR3. The gate electrode GE may be formed as a single layer using only one or a mixture of materials selected from a group consisting of copper (Cu), molybdenum (Mo), tungsten (W), aluminum neodymium (AlNd), titanium (Ti), aluminum (Al), silver (Ag), and an alloy thereof, or may be formed as a double layer or multilayer structure of molybdenum (Mo), titanium (Ti), copper (Cu), aluminum (Al), or silver (Ag) which is a low-resistance material to reduce a line resistance.

The interlayer insulating layer ILD may be located on the gate electrode GE. The interlayer insulating layer ILD may include a same material as the gate insulating layer GI or may include one or more materials selected from the material exemplified as a configuration material of the gate insulating layer GI.

The first transistor electrode TE1 and the second transistor electrode TE2 may be located on the interlayer insulating layer ILD. The first transistor electrode TE1 of the transistor T may contact the first contact area of the active pattern ACT through a contact hole passing through the interlayer insulating layer ILD and the gate insulating layer GI. The first transistor electrode TE1 may be a first source electrode in case that the first contact area is the source area.

The second transistor electrode TE2 of the transistor T may contact the second contact area of the other end of the active pattern ACT through a contact hole passing through the interlayer insulating layer ILD and the gate insulating layer GI. The second transistor electrode TE2 may be a second drain electrode in case that the second contact area is the drain area.

Each of the first transistor electrode TE1 and the second transistor electrode TE2 may include a same material as the gate electrode GE or may include one or more materials selected from materials exemplified as a configuration material of the gate electrode GE.

The passivation layer PSV may be located on the first transistor electrode TE1 and the second transistor electrodes TE2. The passivation layer PSV (for example, a protective layer) may be an inorganic layer (or an inorganic insulating layer) including an inorganic material or an organic layer (or an organic insulating layer) including an organic material. The inorganic layer may include, for example, at least one of a metal oxide such as silicon oxide (SiOx), silicon nitride (SiNx), silicon oxynitride (SiOxNy), or aluminum oxide (AlOx). The organic layer may include, for example, at least one of acrylic resin (polyacrylates resin), epoxy resin, phenolic resin, polyamides resin, polyimides resin, unsaturated polyesters resin, polyphenylene ethers resin, polyphenylene sulfides resin, and benzocyclobutene resin.

According to an embodiment, the passivation layer PSV may include a same material as the interlayer insulating layer ILD, but is not limited thereto. The passivation layer PSV may be provided as a single layer, but may also be provided as multiple layers of at least two or more layers.

The via layer VIA may be located on the passivation layer PSV. The via layer VIA may include a same material as the passivation layer PSV or may include one or more materials selected from materials exemplified as a configuration material of the passivation layer PSV. In an embodiment, the via layer VIA may be an organic layer including an organic material.

The display element layer DPL may be located on the pixel circuit layer PCL. The display element layer DPL may include a light emitting element LD that emits light. The first to third sub-pixels SP1 to SP3 may include first to third light emitting elements LD1 to LD3, respectively.

The first light emitting element LD1 may include an anode electrode AE, the first light emitting layer EML1, and a cathode electrode CE. The second light emitting element LD2 may include an anode electrode AE, the second light emitting layer EML2, and a cathode electrode CE. The third light emitting element LD3 may include an anode electrode AE, the third light emitting layer EML3, and a cathode electrode CE. For example, the first to third light emitting elements LD1 to LD3 may be a front surface light emitting type organic light emitting element.

The anode electrode AE of each sub-pixel SP may be located in the emission areas EMA1, EMA2, and EMA3, and may be spaced apart from each other. The anode electrode AE of each sub-pixel SP may be electrically connected to the first transistor electrode TE1 of the transistor T of each sub-pixel SP through a contact hole passing through the via layer VIA and the passivation layer PSV.

A pixel defining layer (or a bank) PDL may be located on the anode electrode AE. The pixel defining layer PDL may define (or partition) the emission areas EMA1, EMA2, and EMA3 of each sub-pixel SP. The pixel defining layer PDL may include an opening partially exposing the anode electrode AE of each sub-pixel SP. In this case, the anode electrode AE of FIG. 17 may include the first to third anode electrodes AE1, AE2, and AE3 of FIG. 6.

The pixel defining layer PDL may be an organic insulating layer including an organic material. The organic material may include acryl resin, epoxy resin, phenolic resin, polyamide resin, polyimide resin, and the like. However, the disclosure is not limited thereto, and the pixel defining layer PDL may be an inorganic insulating layer including an inorganic material.

According to an embodiment, the pixel defining layer PDL may include a light absorbing material or may be coated with a light absorbing material to serve to absorb light incident from an outside. For example, the pixel defining layer PDL may include a carbon-based black pigment. However, the disclosure is not necessarily limited thereto, and the pixel defining layer PDL may include an opaque metal material such as chromium (Cr), molybdenum (Mo), an alloy of molybdenum (Mo) and titanium (Ti) (MoTi), tungsten (W), vanadium (V), niobium (Nb), tantalum (Ta), manganese (Mn), cobalt (Co), or nickel (Ni).

A light emitting layer EML of each sub-pixel SP may be located on the anode electrode AE exposed by the pixel defining layer PDL. The cathode electrode CE may be located on the light emitting layer EML. The cathode electrode CE may be located over the entire first to third sub-pixels SP1 to SP3. For example, the cathode electrode CE may be provided as a common electrode, but is not necessarily limited thereto. The light emitting layer EML of FIG. 17 may include the first to third organic light emitting layers EL1, EL2, and EL3 of FIG. 6.

The cathode electrode CE may include a metal layer of Ag(silver), Mg(magnesium), Al(aluminum), Pt(platinum), Pd(palladium), Au(gold), Ni(nickel), Nd(neodymium), Ir(iridium), Cr(chromium), an alloy thereof, and the like, and/or a transparent conductive layer of indium tin oxide (ITO), indium zinc oxide (IZO), zinc oxide (ZnO), indium tin zinc oxide (ITZO), and the like. According to an embodiment, the cathode electrode CE may be formed as multiple layers of two or more layers including a metal thin layer, for example, three layers of ITO/Ag/ITO. The cathode electrode CE of FIG. 17 may be substantially the same as the cathode electrode CE of FIG. 6.

The thin film encapsulation layer TFE may be located on the display element layer DPL. The thin film encapsulation layer TFE may have a single layer structure or a multiple layer structure. The thin film encapsulation layer TFE may include an insulating layer covering the light emitting element LD. The thin film encapsulation layer TFE may include at least one inorganic layer and at least one organic layer. For example, the thin film encapsulation layer TFE may have a structure in which an inorganic layer and an organic layer are alternately stacked. For example, the thin film encapsulation layer TFE may include a first inorganic layer, an organic layer located on the first inorganic layer, and a second inorganic layer located on the organic layer.

A sensing layer TS may be located on the thin film encapsulation layer TFE. The sensing layer TS may include a first insulating layer INS1, a first conductive layer MT1, a second insulating layer INS2, a second conductive layer MT2, and/or a third insulating layer INS3.

The first insulating layer INS1 may be located on the thin film encapsulation layer TFE. The first insulating layer INS1 may be an inorganic insulating layer including an inorganic material. The inorganic insulating layer may include an inorganic insulating material such as silicon oxide (SiOx), silicon nitride (SiNx), silicon oxynitride (SiOxNy), aluminum oxide (AlxOy), titanium oxide (TiOx), tantalum oxide (TaxOy), hafnium oxide (HfOx), or zinc oxide (ZnOx). According to an embodiment, the first insulating layer INS1 may be omitted or may be configured as the uppermost layer of the thin film encapsulation layer TFE.

The first conductive layer MT1 may be located on the first insulating layer INS1. The first conductive layer MT1 may be partially opened so as not to overlap the light emitting element LD of each sub-pixel SP in the third direction DR3. For example, the first conductive layer MT1 may be located so as to overlap the non-emission area NEA around the emission areas EMA1, EMA2, and EMA3.

The first conductive layer MT1 may include a metal layer or a transparent conductive layer. For example, the metal layer may include molybdenum, titanium, copper, aluminum, and an alloy thereof. The transparent conductive layer may include one of indium tin oxide (ITO), indium zinc oxide (IZO), zinc oxide (ZnO), indium tin zinc oxide (ITZO), PEDOT, or a metal nanowire, but is not necessarily limited thereto. The first conductive layer MT1 may form a connection electrode connecting sensing electrodes.

The second insulating layer INS2 may be located on the first conductive layer MT1. The second insulating layer INS2 may include a same material as the first insulating layer INS1 described above, or may include one or more materials selected from the materials exemplified as the configuration material of the first insulating layer INS1.

The second conductive layer MT2 may be located on the second insulating layer INS2. The second conductive layer MT2 may be partially opened so as not to overlap the light emitting element LD of each sub-pixel SP in the third direction DR3. For example, the second conductive layer MT2 may be located to overlap the non-emission area NEA around the emission areas EMA1, EMA2, and EMA3.

The second conductive layer MT2 may include a same material as the first conductive layer MT1 described above, or may include one or more materials selected from the materials exemplified as the configuration material of the first conductive layer MT1.

The second conductive layer MT2 may be electrically connected to the first conductive layer MT1 through a contact hole passing through the second insulating layer INS2. The second conductive layer MT2 may form sensing electrodes.

The third insulating layer INS3 may be located on the second conductive layer MT2. The third insulating layer INS3 may be an organic insulating layer including an organic material. However, the disclosure is not necessarily limited thereto, and according to an embodiment, the third insulating layer INS3 may include an inorganic layer or may have a structure in which an organic layer and an inorganic layer are alternately stacked.

A light blocking layer LBP may be located on the display element layer DPL, the thin film encapsulation layer TFE, and/or the sensing layer TS. The light blocking layer LBP may include an opening overlapping the light emitting element LD. For example, the light blocking layer LBP may be located to overlap the non-emission area NEA around the emission areas EMA1, EMA2, and EMA3.

The light blocking layer LBP may include a light blocking material to prevent light leakage and color mixing defects. For example, the light blocking layer LBP may include a black matrix, but is not necessarily limited thereto. According to an embodiment, the light blocking layer LBP may include carbon black (CB) and/or titan black (TiBK).

A color filter layer CFL may be located on the light blocking layer LBP. The color filter layer CFL may include color filters CF1 to CF3 that match a color of each sub-pixel SP. As the color filters CF1 to CF3 that match the color of the first to third sub-pixels SP1 to SP3, respective, are located, a full color of image may be displayed.

The color filter layer CFL may include a first color filter CF1 located in the first sub-pixel SP1 to selectively transmit light emitted from the first sub-pixel SP1, a second color filter CF2 located in the second sub-pixel SP2 to selectively transmit light emitted from the second sub-pixel SP2, and a third color filter CF3 located in the third sub-pixel SP3 to selectively transmit light emitted from the third sub-pixel SP3.

In an embodiment, the first color filter CF1, the second color filter CF2, and the third color filter CF3 may be a red color filter, a green color filter, and a blue color filter, respectively, but are not necessarily limited thereto.

The first color filter CF1 may include a color filter material that selectively transmits light of a first color (or red). For example, the first color filter CF1 may include a red color filter material in case that the first sub-pixel SP1 is a red sub-pixel.

The second color filter CF2 may include a color filter material that selectively transmits light of a second color (or green). For example, the second color filter CF2 may include a green color filter material in case that the second sub-pixel SP2 is a green sub-pixel.

The third color filter CF3 may include a color filter material that selectively transmits light of a third color (or blue). For example, the third color filter CF3 may include a blue color filter material in case that the third sub-pixel SP3 is a blue sub-pixel.

An overcoat layer OC may be provided on the color filter layer CFL. The overcoat layer OC may include various materials suitable for protecting the lower layers from a foreign substance such as dust or moisture. For example, the overcoat layer OC may include at least one of an inorganic insulating layer and an organic insulating layer. For example, the overcoat layer OC may include epoxy, but embodiments are not limited thereto.

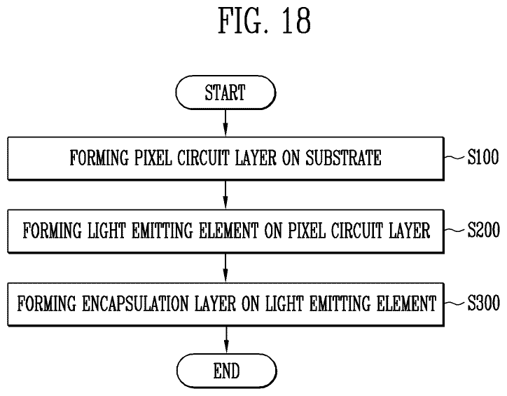

Hereinafter, a method of manufacturing the display device DD is described with reference to FIG. 18.

FIG. 18 is a flowchart illustrating a method of manufacturing a display device according to an embodiment. The method of manufacturing the display device DD according to the disclosure may be a method of manufacturing the display device DD using the mask for deposition MSK and the deposition apparatus EA described above.

Referring to FIG. 18, the method of manufacturing the display device DD may include forming a pixel circuit layer on a substrate (S100), forming a light emitting element on the pixel circuit layer (S200), and forming an encapsulation layer on the light emitting element (S300).

Referring to FIGS. 17 and 18, in forming the pixel circuit layer on the substrate (S100), circuit elements may be patterned on the substrate SUB (the substrate SUB may correspond to the base layer BSL), and the pixel circuit layer PCL may be provided.

According to an embodiment, a conductive layer, an insulating layer, and the like on the substrate SUB may be formed based on a general process for manufacturing a semiconductor device. For example, the conductive layer or the insulating layer on the substrate SUB may be formed by a photolithography process, may be etched by various methods (wet etching, dry etching, and the like), and may be deposited by various methods (sputtering, chemical vapor deposition, and the like). The disclosure is not necessarily limited to a specific example.

In forming the pixel circuit layer on the substrate (S100), transistors T may be patterned on the substrate SUB.

In forming the light emitting element on the pixel circuit layer (S200), the anode electrode AE, the light emitting layer EML1 to EML3, and the cathode electrode CE may be formed to form the first to third light emitting elements LD1 to LD3.

In forming the light emitting element on the pixel circuit layer (S200), the anode electrodes AE may be patterned, and the pixel defining layer PDL overlapping the anode electrodes AE may be patterned.

Thereafter, depositing the first to third light emitting layers EML1 to EML3 on the anode electrodes AE may be performed. The first to third light emitting layers EML1 to EML3 may be deposited using the mask for deposition MSK and the deposition apparatus EA described above. For example, materials for forming the first to third light emitting layers EML1 to EML3 may be located on the anode electrodes AE by passing through the mask MSK. To this end, a pattern of the mask MSK may correspond to a pattern of the first to third light emitting layers EML1 to EML3. Thereafter, the cathode electrode CE may be formed on the first to third light emitting layers EML1 to EML3.

In forming the encapsulation layer on the light emitting element (S300), an encapsulation layer TFE may be formed on the light emitting element LD1 to LD3. Lower layers of the encapsulation layer TFE may be passivated.

Thereafter, according to an embodiment, the sensing layer TS, the light blocking layer LBP, and the color filter layer CFL may be located, and the display device DD according to an embodiment may be provided.

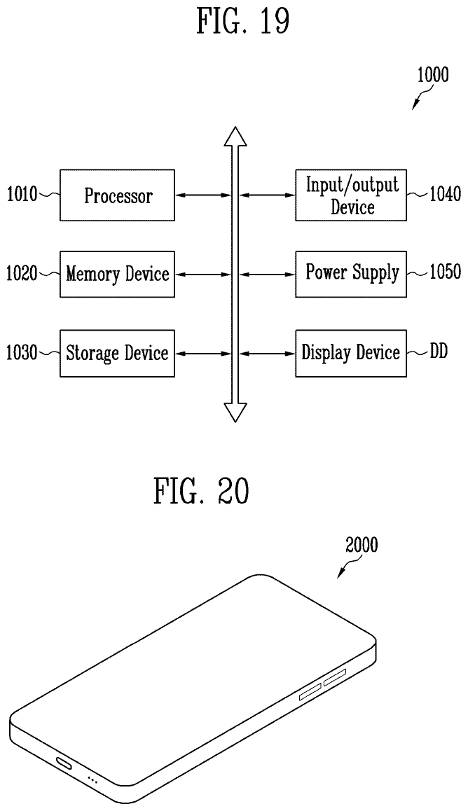

Hereinafter, with reference to FIGS. 19 to 21, an electronic device 1000 including the display device DD manufactured according to the manufacturing method of the display device DD described above is described.

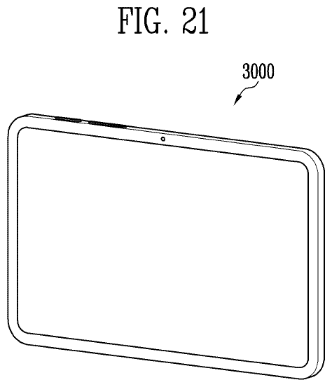

FIG. 19 is a block diagram illustrating an embodiment of an electronic device including the display device of FIG. 17. FIG. 20 is a perspective view illustrating an example of a smartphone that may be implemented using the electronic device of FIG. 19. FIG. 21 is a perspective view illustrating an example of a tablet computer that may be implemented using the electronic device of FIG. 19.

Referring to FIG. 19, the electronic device 1000 may include a processor 1010, a memory device 1020, a storage device 1030, an input/output device 1040, a power supply 1050, and a display device DD.

In embodiments, as shown in FIG. 20, the electronic device 1000 may be implemented as the smartphone 2000. In other embodiments, as shown in FIG. 21, the electronic device 1000 may be implemented as the tablet computer 3000. However, this is an example, and the electronic device 1000 is not limited thereto. For example, the electronic device 1000 may be an electronic device (or a computing system) including the above-described display device DD, such as a digital television (TV), a 3D TV, a personal computer (PC), a home appliance, a laptop computer, a mobile phone, a video phone, a smart pad, a smart watch, a head mounted display device, a personal digital assistant (PDA), a portable multimedia player (PMP), a digital camera, a music player, a portable game console, or a navigation system.

The processor 1010 may perform various tasks and calculations. In embodiments, the processor 1010 may include an application processor, a graphic processing unit, a microprocessor, a central processing unit (CPU), or the like. The processor 1010 may be connected to other components of the electronic device 1000 through a bus system. In embodiments, the bus system may include a peripheral component interconnect (PCI) bus. The processor 1010 may provide a data stream to be displayed on the display device DD to the display device DD.

The memory device 1020 may be provided as a working memory and/or buffer memory of the electronic device 1000 and/or the processor 1010. In embodiments, the memory device 1020 may include volatile memory devices such as a dynamic random access memory (DRAM), a static random access memory (SRAM), and a mobile DRAM.

The storage device 1030 may store data in response to control of the processor 1010. The storage device 1030 may include a nonvolatile storage medium that maintains data even though power of the electronic device 1000 is cut off. In embodiments, the storage device 1030 may include a solid state drive (SSD), a hard disk drive (HDD), or the like.

The input/output device 1040 may include user input devices such as a keyboard, a keypad, a touchpad, a touchscreen, and a mouse, and output devices such as a speaker and a printer.

The power supply 1050 may supply power required for an operation of the electronic device 1000. For example, the power supply 1050 may be a power management integrated circuit (PMIC). For example, the power supply 1050 may include a battery.

The display device DD may display an image in response to control of the processor 1010. The display device DD may be connected to other components of the electronic device 1000 through a bus system and/or another communication link. The display device DD may be implemented as the display device DD of FIG. 18. The display device DD may display an image on the pixels PXL.

Although the disclosure has been described with reference to the above-described embodiments, it will be understood by those skilled in the art that the disclosure may be variously corrected and changed without departing from the spirit and scope of the disclosure as set forth in the claims below.

What is claimed is:

1. A mask for deposition comprising:
a base substrate;
a first silicon layer covering at least a portion of the base substrate;
a second silicon layer located on the base substrate and the first silicon layer; and
a plurality of cell opening areas spaced apart from each other,
wherein a plurality of first opening patterns overlapping each of the plurality of cell opening areas and passing through the second silicon layer in a third direction are defined in the second silicon layer,
at least one second opening pattern passing through the base substrate and the first silicon layer and overlapping the plurality of cell opening areas in the third direction is defined in the base substrate and the first silicon layer, and
the second silicon layer includes a first portion spaced apart from the base substrate in the third direction and a second portion contacting a portion of the base substrate.

2. The mask for deposition according to claim 1, wherein a thermal expansion rate of the second silicon layer is greater than a thermal expansion rate of the base substrate.

3. The mask for deposition according to claim 2, wherein the first portion includes a (1_a)-th portion and a (1_b)-th portion symmetrically located with respect to a vertical axis parallel to the third direction, and
the second portion includes a (2_a)-th portion extending from the (1_a)-th portion and a (2_b)-th portion extending from the (1_b)-th portion.

4. The mask for deposition according to claim 3, wherein the base substrate includes an a-th portion overlapping the (1_a)-th portion and a b-th portion overlapping the (2_a)-th portion, and
a thermal expansion direction of the b-th portion is a direction opposite to a thermal expansion direction of the (1_a)-th portion.

5. The mask for deposition according to claim 4, wherein a thermal expansion degree of the b-th portion is less than a thermal expansion degree of the (1_a)-th portion.

6. The mask for deposition according to claim 3, comprising:
a trench overlapping the plurality of cell opening areas in the third direction and recessed in a first direction or a direction opposite to the first direction crossing the third direction.

7. The mask for deposition according to claim 6, wherein the trench comprises:
a first trench recessed in the direction opposite to the first direction and overlapping the (1_a)-th portion; and
a second trench recessed in the first direction and overlapping the (1_b)-th portion.

8. The mask for deposition according to claim 6, wherein the trench overlaps the first portion in the third direction, and does not overlap the first opening patterns in the third direction.

9. The mask for deposition according to claim 1, wherein the first silicon layer includes silicon oxide, and the second silicon layer includes silicon nitride.

10. A method of manufacturing a mask for deposition, the method comprising:
forming a first silicon layer on a base substrate;
patterning the first silicon layer to form first to third units corresponding to first to third cell opening areas, respectively;
forming a second silicon layer on the base substrate and the first silicon layer;
patterning the second silicon layer to form first preliminary opening patterns in each of the first to third cell opening areas;
removing at least a portion of each of the second silicon layer and the base layer so that a back surface of the first silicon layer is exposed; and
removing the first to third units.

11. The method according to claim 10, wherein removing the first to third units is performed in a wet etching process.

12. The method according to claim 11, wherein a thermal expansion rate of the second silicon layer is greater than a thermal expansion rate of the base substrate.

13. The method according to claim 12, wherein the second silicon layer includes a first portion spaced apart from the base substrate in a third direction and a second portion contacting a portion of the base substrate,
the first portion includes a (1_a)-th portion and a (1_b)-th portion symmetrically located with respect to a vertical axis parallel to the third direction, and
the second portion includes a (2_a)-th portion extending from the (1_a)-th portion and a (2_b)-th portion extending from the (1_b)-th portion.

14. The method according to claim 13, wherein the base substrate includes an a-th portion overlapping the (1_a)-th portion and a b-th portion overlapping the (2_a)-th portion, and
a thermal expansion direction of the b-th portion is a direction opposite to a thermal expansion direction of the (1_a)-th portion.

15. The method according to claim 14, wherein a thermal expansion degree of the b-th portion is less than a thermal expansion degree of the (1_a)-th portion.

16. The method according to claim 13, comprising:
a trench overlapping one of the first to third cell opening areas in the third direction and recessed in a first direction or a direction opposite to the first direction crossing the third direction.

17. The method according to claim 16, wherein in removing the first to third units, one of the first to third units is removed and the trench is formed in a location of the one of the first to third units.

18. A method of manufacturing a display device, the method comprising:
forming a pixel circuit layer on a substrate; and
forming a light emitting element on the pixel circuit layer,
wherein forming the light emitting element comprises depositing a light emitting layer using a deposition apparatus,
wherein the deposition apparatus comprises a mask for deposition comprising:
a base substrate;
a first silicon layer covering at least a portion of the base substrate;
a second silicon layer located on the base substrate and the first silicon layer; and
a plurality of cell opening areas spaced apart from each other,
wherein a plurality of first opening patterns overlapping each of the plurality of cell opening areas and passing through the second silicon layer in a third direction are defined in the second silicon layer,
at least one second opening pattern passing through the base substrate and the first silicon layer and overlapping the plurality of cell opening areas in the third direction is defined in the base substrate and the first silicon layer, and
the second silicon layer includes a first portion spaced apart from the base substrate in the third direction and a second portion contacting a portion of the base substrate.
